(19) United States
(12) Patent Application Publication
(10) Pub. No.: US 2016/0111570 A1
(43) Pub. Date: Apr. 21, 2016

(54) RIBBON-FREE SOLAR CELL MODULE AND METHOD FOR PREPARING SAME

(71) Applicant: NANJING SUNPORT POWER CO. LTD., Jiangsu (CN)

(72) Inventors: Zhilei LI, Nanjing (CN); Zhonglin LU, Nanjing (CN); Wenting SHENG, Nanjing (CN); Fengming ZHANG, Nanjing (CN)

(73) Assignee: NANJING SUNPORT POWER CO. LTD., Nanjing, Jiangsu (CN)

(21) Appl. No.: 14/894,601

(22) PCT Filed: Jul. 30, 2013
(86) PCT No.: PCT/CN2013/080450

§ 371 Date: Nov. 30, 2015

(30) Foreign Application Priority Data
May 30, 2013 (CN) 201310215117.7

(51) Int. Cl. H01L 31/049; H01L 31/18; H01L 31/048

(52) U.S. Cl. CPC H01L 31/049; H01L 31/0481; H01L 31/18

(57) ABSTRACT

A ribbon-free solar cell module and a method for preparing the same are provided. The solar cell module is in a five-layer structure, including a first layer of conductive back plate, a second layer of conductive adhesive connection joints, a third layer of back contact cells, a fourth layer of packaging material, and a fifth layer of tempered glass which are successively laminated together, wherein the first layer of conductive back plate is in a novel laminated structure. Such a design provides a ribbon-free solar cell module and a method for preparing the same which are low in cost, and easy to implement.

### FIELD OF THE INVENTION

The present invention relates to a ribbon-free solar cell module and a method for preparing the same, and belongs to the field of solar cell modules.

### BACKGROUND OF THE INVENTION

In the existing solar cell module, when a plurality of crystalline silicon solar cells are packaged in series into a large module, a tin coated copper ribbon is commonly selected and soldered to the positive and negative bus bars of adjacent cells to achieve the series connection between a plurality of cells. Such conventional ribbon series connection manner is so visualized and simple that it is widely used, but that method has several major disadvantages: 1) the tin-coated layer of the tin-coated copper ribbon is commonly a SnPb alloy, the Pb content is commonly 40% or so, and unfortunately excessive use of Pb poses a serious potential risk to the environment; 2) when the tin-coated copper ribbon is in use, the soldering temperature is commonly above 300 degrees, so that the heat stress can easily lead to the bending and breaking of the crystalline silicon cells, and especially at present, along with the progress in cell technology, the used silicon wafers become so thin that if the wafer thickness is less than 160 um, the existing high-temperature soldering technology is completely inapplicable; and 3) since the ribbon itself shades the cells, a considerable power packaging loss is caused in the process of packaging the cells in a module, packaging loss for polycrystalline and monocrystalline cells being commonly greater than 3% and 5% respectively. Therefore, developing a novel ribbon-free cell module structure and a method for preparing the same seems extremely important, so that a back contact cell module came into being in that context. The Energy Research Centre of the Netherlands (ECN) and other research institutions presented an interconnection way based on a conductive foil circuit, but the structure and preparation process route of that back contact cell module are obviously rather complex, the materials used are rather expensive, and the production efficiency is low.

### SUMMARY OF THE INVENTION

Object of the invention: The aim of the present invention is to provide a ribbon-free solar cell module and a method for preparing the same which are low in cost, and easy to implement in view of the shortcomings of the prior art.

### Technical Solution

In order to reduce costs, to have an easy implementation, and not to need any ribbons, the present invention discloses a ribbon-free solar cell module, including a first layer of conductive back plate, a second layer of conductive adhesive connection joints, a third layer of back contact cells, a fourth layer of packaging material, and a fifth layer of tempered glass which are successively laminated together; the first layer of conductive back plate employs a back plate layer one of fluoropolymer, a back plate layer two of PET material, a back plate layer three of metal circuit and a back plate layer four of sealing material which are successively laminated together. The back plate layer three of metal circuit is made of copper or aluminum, and ranges from 20 to 60 um in thickness. The back plate four of sealing material ranges from 50 to 200 um in thickness.

In order to mask the metal circuit, improve the optical reflectivity of the back plate and the output power of the module, and cause the whole module to look more uniform and good, a back plate layer five of isodielectric material and a back plate layer six of sealing material are laminated additionally to the back plate layer four of sealing material; the total thickness of the back plate layer four of sealing material, the back plate layer five of isodielectric material and the back plate layer six of sealing material ranges from 50 to 200 um.

A method for preparing a ribbon-free solar cell module includes the following steps:
(a) printing conductive glue on a first layer of conductive back plate by dispensing or stencil printing, the positions for printing conductive adhesive being matched with the electrode point positions of a third layer of back contact cells to form a second layer of conductive adhesive connection joints;
(b) placing the third layer of back contact cells accurately on the second layer of conductive adhesive connection joints, so as to ensure that the electrode points of the third layer of back contact cells correspond one-to-one with the positions of the second layer of conductive adhesive connection joints; and
(c) laying a fourth layer of packaging material and a fifth layer of tempered glass on the third layer of back contact cells.

In the step (a), the curing temperature of the conductive glue ranges from 80 to 140° C.; the conductive glue is made of silicone based or epoxy resin based material, conductive particles dispersed therein being Ag or Ag-plated Cu particles; the conductive glue connection joints of the second layer of conductive adhesive connection joints are each in a cylindrical or conical shape, ranging from 1 to 4 mm in base diameter and from 0.1 to 0.5 mm in height.

### Beneficial Effects

Compared with the prior art, the present invention has the significant advantages that the cell module contains no ribbon, the preparation method is simple and reliable, the conductive back plate in a special structure is used, the sealing material on the bottom layer is integrated, the sealing material covering the metal circuit also keeps the circuit surface away from moisture and oxidation, and low temperature curing conductive adhesive is used to achieve the low temperature curing of the conductive adhesive at the same time of the lamination process, so as to replace the existing complex packaging process route of the back contact cell module, and meet the requirements in packaging technology for the ribbon-free back contact cell module which is low in cost, large in capacity, and high in yield.

### BRIEF DESCRIPTION OF THE DRAWINGS

FIG. 1 is a structural diagram of a ribbon-free solar cell module of the present invention;

FIG. 2 is a diagram of a layer structure of a ribbon-free solar cell module of the present invention;

FIG. 3 is a structural diagram of a conductive back plate of the present invention; and

FIG. 4 is a diagram of an improved structure of a conductive back plate of the present invention.

### DETAILED DESCRIPTION OF THE EMBODIMENTS

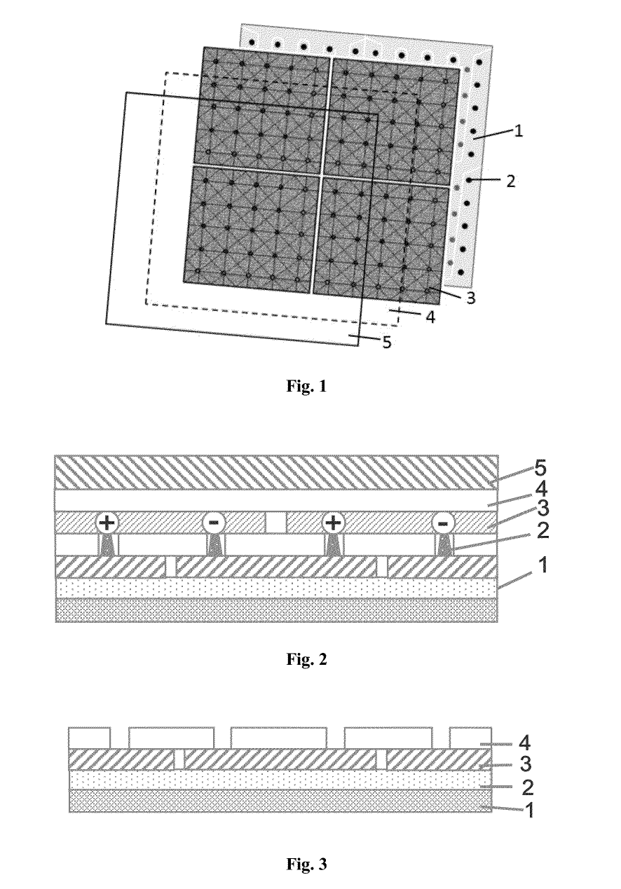

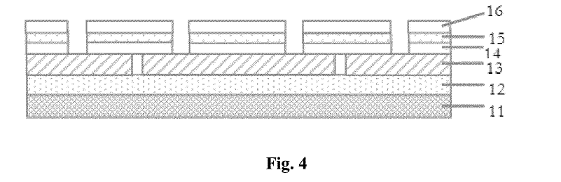

The present invention is further described below in conjunction with the drawings. As shown in FIGS. 1 and 2, the solar cell module of the present invention is in a five-layer structure, including a first layer of conductive back plate 1, a second layer of conductive adhesive connection joints 2, a third layer of back contact cells 3, a fourth layer of packaging material 4 and a fifth layer of tempered glass 5 which are successively laminated together. The method for preparing such a solar cell module includes printing conductive glue on the first layer of conductive back plate 1 by dispensing or stencil printing, the positions for printing conductive adhesive being matched with the electrode point positions of the third layer of back contact cells 3 to form the second layer of conductive adhesive connection joints 2, the curing temperature of the conductive glue ranging from 80 to 140° C., the conductive glue being made of silicone based or epoxy resin based material, conductive particles dispersed therein being Ag or Ag-plated Cu particles, each conductive glue connection joint being in a cylindrical or conical shape, ranging from 1 to 4 mm in base diameter and from 0.1 to 0.5 mm in height; placing the third layer of back contact cells 3 accurately on the second layer of conductive adhesive connection joints 2, so as to ensure that the electrode points of the third layer of back contact cells 3 correspond one-to-one with the positions of the second layer of conductive adhesive connection joints 2; and laying the fourth layer of packaging material 4 and the fifth layer of tempered glass 5 on the third layer of back contact cells 3. As shown in FIG. 3, the first layer of conductive back plate 1 employs a back plate layer one of fluoropolymer 11, a back plate layer two of PET material 12, a back plate layer three of metal circuit 13 and a back plate four of sealing material 14 which are successively laminated together; the back plate layer three of metal circuit 13 is made of copper or aluminum, and ranges from 20 to 60 um in thickness; the back plate four of sealing material 14 ranges from 50 to 200 um in thickness. Thus, the solar cell module disclosed by the present disclosure contains no ribbon, the preparation method is simple and reliable, the conductive back plate in a special structure is used, the sealing material on the bottom layer is integrated, the metal circuit on the back plate is also protected by the sealing material, and low temperature curing conductive adhesive is used to achieve the low temperature curing of the conductive adhesive at the same time of the lamination process, so as to replace the existing complex packaging process route of the back contact cell module, and meet the requirements in packaging technology for the ribbon-free back contact cell module which is low in cost, large in capacity, and high in yield. However, as shown in FIG. 4, the first layer of conductive back plate 1 may be in an improved structure, and may employ a back plate layer one of fluoropolymer 11, a back plate layer two of PET material 12, a back plate layer three of metal circuit 13, a back plate layer four of sealing material 14, a back plate layer five of isodielectric material 15 and a back plate layer six of sealing material 16 which are successively laminated together; the total thickness of the back plate layer four of sealing material 14, the back plate layer five of isodielectric material 15 and the back plate layer six of sealing material 16 ranges from 150 to 200 um. The metal circuit may be masked by such an improvement of the first layer of conductive back plate 1, so as to enhance the optical reflectivity of the back plate and the output power of the module, and cause the whole module to look more uniform and good.

1. A ribbon-free solar cell module, comprising a first layer of conductive back plate, a second layer of conductive adhesive connection joints, a third layer of back contact cells, a fourth layer of packaging material, and a fifth layer of tempered glass which are successively laminated together, wherein the first layer of conductive back plate employs a back plate layer one of fluoropolymer, a back plate layer two of PET material, a back plate layer three of metal circuit and a back plate layer four of sealing material which are successively laminated together.

2. The ribbon-free solar cell module according to claim 1, wherein the back plate layer three of metal circuit is made of copper or aluminum, and ranges from 20 to 60 um in thickness.

3. The ribbon-free solar cell module according to claim 1, wherein the back plate layer four of sealing material ranges from 50 to 200 um in thickness.

4. The ribbon-free solar cell module according to claim 1, wherein a back plate layer five of isodielectric material and a back plate layer six of sealing material are laminated additionally to the back plate layer four of sealing material; and the total thickness of the back plate layer four of sealing material, the back plate layer five of isodielectric material and the back plate layer six of sealing material ranges from 50 to 200 um.

5. The ribbon-free solar cell module according to claim 1, wherein the different layers of material in the first layer of conductive back plate are made by bonding and hot pressing.

6. The ribbon-free solar cell module according to claim 1, wherein the third layer of back contact cells is interconnected with the back plate layer three of metal circuit by conductive glue cured at a low temperature.

7. A method for preparing a ribbon-free solar cell module, comprising the following steps:
(a) printing conductive glue on a first layer of conductive back plate by dispensing or stencil printing, positions for printing conductive adhesive being matched with electrode point positions of a third layer of back contact cells to form a second layer of conductive adhesive connection joints;
(b) placing the third layer of back contact cells accurately on the second layer of conductive adhesive connection joints to ensure that the electrode points of the third layer of back contact points correspond one-to-one with positions of the second layer of conductive adhesive connection joints; and
(c) laying a fourth layer of packaging material and a fifth layer of tempered glass on the third layer of back contact cells.

8. The method for preparing a ribbon-free solar cell module according to claim 7, wherein in the step (a), the curing temperature of the conductive glue ranges from 80 to 140° C.; the conductive glue is made of silicone based or epoxy resin based material, conductive particles dispersed therein being Ag or Ag-plated Cu particles; conductive glue connection joints of the second layer of conductive adhesive connection joints are each in a cylindrical or conical shape, ranging from 1 to 4 mm in base diameter and from 0.1 to 0.5 mm in height.
